(19) United States
(12) Patent Application Publication
(10) Pub. No.: US 2026/0068735 A1
(43) Pub. Date: Mar. 5, 2026

(54) FABRICATION METHOD OF SEMICONDUCTOR DEVICE

(71) Applicant: FUJI ELECTRIC CO., LTD., Kanagawa (JP)

(72) Inventor: Kazuhiro KITAHARA, Matsumoto-city (JP)

(21) Appl. No.: 19/245,385

(22) Filed: Jun. 22, 2025

(30) Foreign Application Priority Data
Aug. 29, 2024 (JP) 2024-147133

(51) Int. Cl. H01L 21/56; H01L 21/265; H01L 21/311

(52) U.S. Cl. CPC H01L 21/56

(57) ABSTRACT

Provided is a fabrication method of a semiconductor device, the fabrication method including applying a protective film to a front surface of a semiconductor wafer, patterning the protective film, performing backside processing of the semiconductor wafer in a state in which the protective film that is patterned of the front surface is supported by a support stand in a vacuum chamber, and removing the protective film after the backside processing of the semiconductor wafer is performed. The performing the backside processing may include performing ion implantation into a back surface of the semiconductor wafer. The protective film may be polyimide.

The contents of the following patent application(s) are incorporated herein by reference:
NO. 2024-147133 filed in JP on Aug. 29, 2024.

### BACKGROUND

### 1. Technical Field

The present invention relates to a fabrication method of a semiconductor device.

### 2. Related Art

Patent Document 1 describes “as a front surface protection film, for example, a resist is applied, and a front surface element structure on a front surface side of an n-type semiconductor substrate 10 is protected by a resist film (not illustrated)” ([0039]). Patent Document 2 describes “a resist film is applied to a substrate surface 2 as a front surface protection film 3 at a thickness of, for example, approximately 30 μm” ([0024]). Patent Document 3 describes “a second protective film 130 is formed above a first protective film 120” ([0043]).

### PRIOR ART DOCUMENTS

### Patent Documents

Patent Document 1: WO 2018/179798
Patent Document 2: Japanese Patent Application Publication 2006-54349
Patent Document 3: Japanese Patent Application Publication 2022-182825

### BRIEF DESCRIPTION OF THE DRAWINGS

FIG. 1 is a flowchart representing an example of an operational flow of a fabrication method of a semiconductor device 100 according to an embodiment.

FIG. 2 is a diagram for describing a fabrication method of a semiconductor device 101 according to a comparative example.

FIG. 3 is a diagram for describing the fabrication method of the semiconductor device 100 according to an embodiment.

FIG. 4 is a plan view representing an example of a patterned protective film 130 of a front surface 11 of a semiconductor wafer 10 in the fabrication method of the semiconductor device 100 according to an embodiment.

FIG. 5 is a plan view representing an example of a support stand which supports the patterned protective film 130 of the front surface 11 of the semiconductor wafer 10 in the fabrication method of the semiconductor device 100 according to an embodiment.

FIG. 6 is a flowchart representing an example of a subroutine of step S111 in the operational flow of FIG. 1.

FIG. 7 is a flowchart representing an example of a subroutine of step S115 in the operational flow of FIG. 1.

FIG. 8 illustrates an example of a positioning of a gate runner 48, a well region, and a pad region of the semiconductor device 100 in a top view.

FIG. 9 illustrates an example of a positioning of a passivation film 120 of the semiconductor device 100 in a top view.

FIG. 10 illustrates an example of a positioning of a resist 150 used when the passivation film 120 is patterned.

FIG. 11 illustrates an example of a cross section of the semiconductor device 100 in an active section 110.

FIG. 12 illustrates a relationship between the presence or absence of an anti-bouncing measure and a beam current, and a number of processed sheets.

### DESCRIPTION OF EXEMPLARY EMBODIMENTS

Hereinafter, the present invention will be described through embodiments of the invention, but the following embodiments do not limit the invention according to claims. In addition, not all combinations of features described in the embodiments are essential to the solution of the invention. Note that, in the present specification and the drawings, a repeated description for an element having a substantially same function and configuration is omitted by providing a same reference numeral, and illustration of an element which is not directly associated with the present invention is omitted. Also, in one drawing, an element having the same function and configuration may be provided with a representative reference numeral, omitting the reference numerals for the others.

As used herein, one side in a direction parallel to a depth direction of a semiconductor substrate is referred to as “upper” and the other side is referred to as “lower”. One surface of two main surfaces of a substrate, a layer or other member is referred to as an upper surface, and the other surface is referred to as a lower surface. An “upper” and “lower” direction is not limited to a direction of gravity, or a direction at the time in which the semiconductor module is implemented.

In the present specification, technical matters may be described using orthogonal coordinate axes of an X axis, a Y axis, and a Z axis. The orthogonal coordinate axes merely specify relative positions of components and do not limit a specific direction. For example, the Z axis is not limited to indicate a height direction relative to the ground. Note that a +Z axis direction and a −Z axis direction are directions opposite to each other. When the Z axis direction is described without describing the signs, it means that the direction is parallel to the +Z axis and the −Z axis. In the present specification, orthogonal axes parallel to an upper surface and a lower surface of a semiconductor wafer are set as an X axis and a Y axis. An axis perpendicular to the upper surface and the lower surface of the semiconductor wafer is set as a Z axis. In the present specification, a direction of the Z axis may be referred to as a depth direction. Furthermore, in the present specification, a direction parallel to the upper surface and the lower surface of the semiconductor wafer may be referred to as a horizontal direction, including the X axis and the Y axis.

In the present specification, a case where a term such as “same” or “equal” is mentioned may include a case where an error due to a variation in fabrication or the like is included. The error is, for example, within 10%.

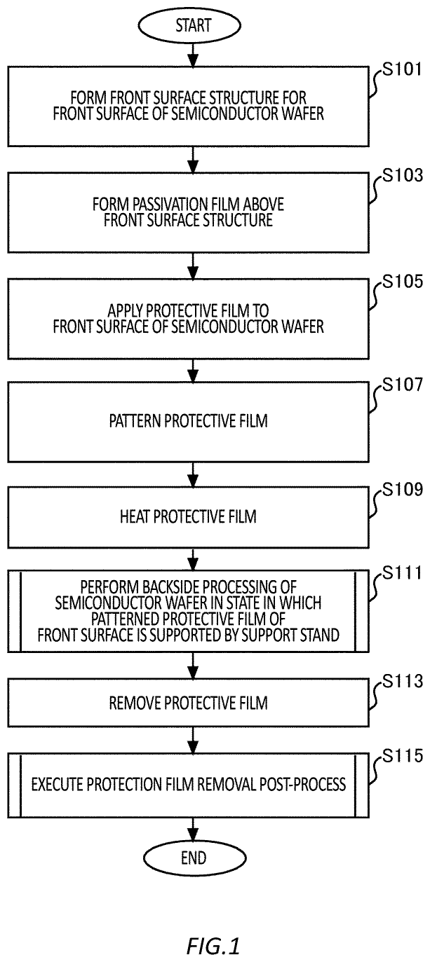

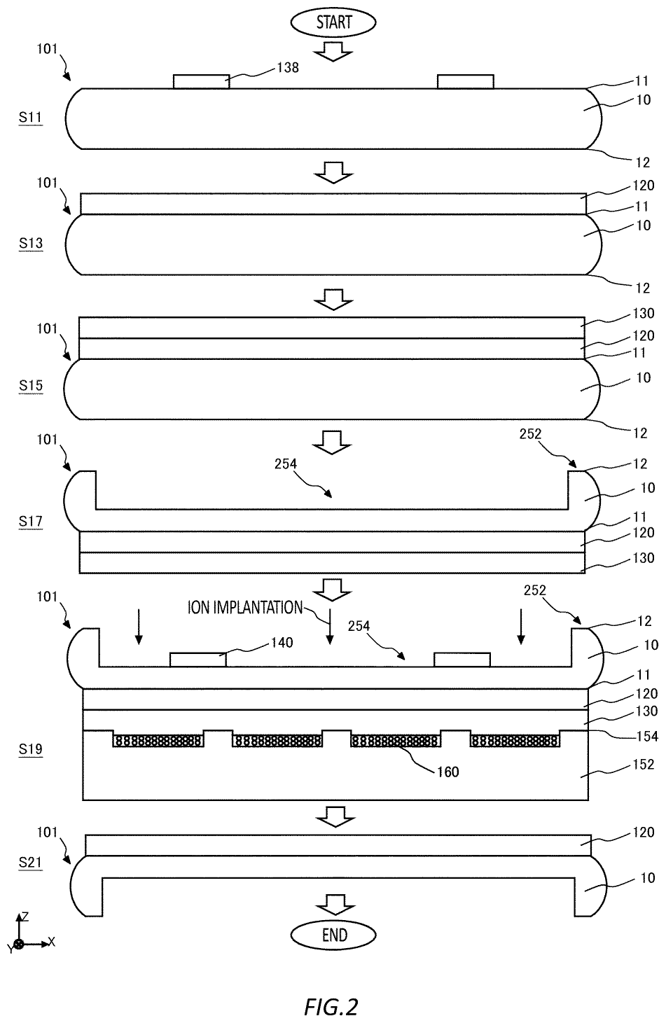

FIG. 1 is a flowchart representing an example of an operational flow of a fabrication method of a semiconductor device 100 according to an embodiment. FIG. 2 is a diagram for describing a fabrication method of a semiconductor device 101 according to a comparative example.

As an example, the semiconductor devices 100 and 101 function as an electric power conversion device such as an inverter. The semiconductor devices 100 and 101 may include diodes such as an insulated gate bipolar transistor (IGBT) and a free wheel diode (FWD) and a reverse conducting (RC)-IGBT obtained by combining these, a MOS transistor, and the like. As an example, the semiconductor devices 100 and 101 function as a pressure sensor. The semiconductor devices 100 and 101 do not need to be limited to these examples. As an example, the semiconductor devices 100 and 101 include an RC-IGBT.

The semiconductor devices 100 and 101 include a semiconductor wafer 10. As an example, a shape in a top view of the semiconductor wafer 10 is substantially circular, and a diameter is 200±5 mm or 300±5 mm. The semiconductor wafer 10 is a substrate formed of a semiconductor material. The semiconductor wafer 10 is a silicon substrate as an example, but a material of the semiconductor wafer 10 is not limited to silicon. A plurality of semiconductor devices 100 may be fabricated by dicing the semiconductor wafer 10. The semiconductor wafer 10 has a front surface 11 and a back surface 12.

The front surface 11 of the semiconductor wafer 10 may be a surface where a front surface structure of an IGBT or an MOS transistor is formed. The front surface structure is, for example, a structure including at least one of a gate pad, a gate insulating film, a source region, a trench portion, an emitter region, a contact region, or a channel region. The front surface 11 of the semiconductor wafer 10 may be a so-called device surface.

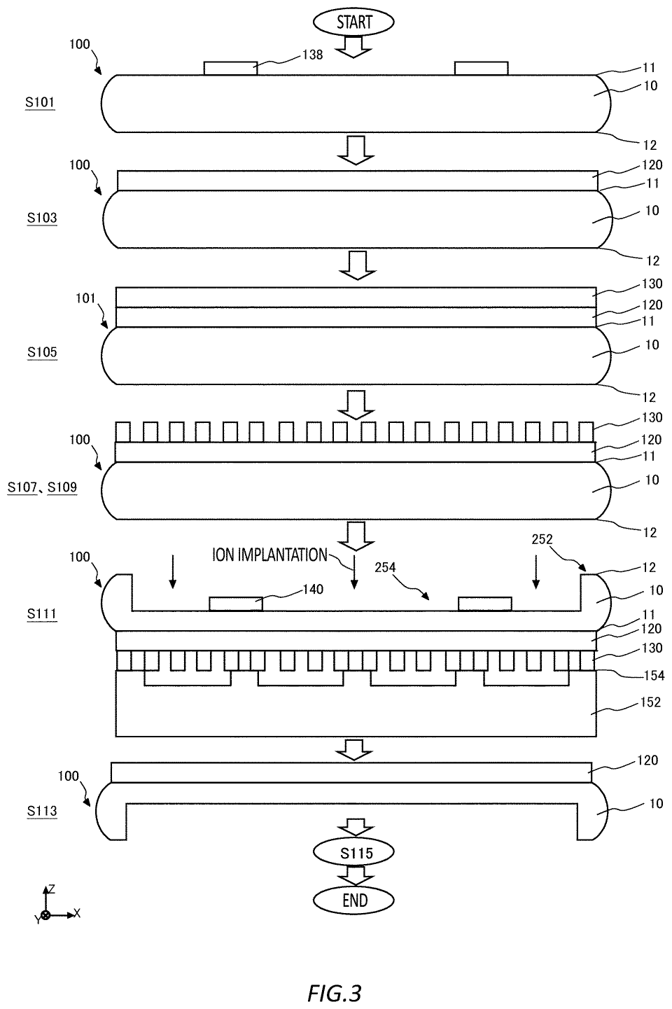

The operational flow of the fabrication method of the semiconductor device 100 according to the present embodiment illustrated in FIG. 1 is started, for example, by preparing the semiconductor wafer 10. The semiconductor wafer 10 to be prepared may be obtained by implanting an impurity into a predetermined region, may be obtained by being annealed, or may be obtained by forming an insulating film, an electrode, a wiring, a pad region, or the like in the front surface 11. Note that in FIG. 2 and FIG. 3, an illustration of components other than the semiconductor wafer 10 in the semiconductor devices 100 and 101 is omitted.

According to the operational flow of FIG. 1, the front surface structure is formed in the front surface 11 of the semiconductor wafer 10 (step S101), and a passivation film 120 is formed above the front surface structure (step S103). Subsequently, a protective film 130 is applied to the front surface 11 of the semiconductor wafer 10 (step S105), the protective film 130 is patterned (step S107), and the protective film 130 is heated after the patterning (step S109). Subsequently, backside processing of the semiconductor wafer 10 is performed in a state in which the protective film 130 that is patterned of the front surface 11 is supported by a support stand 152 in a vacuum chamber (step S111), the protective film 130 is removed (step S113), and various protection film removal post-processes are executed (step S115) to end the operational flow.

Herein, as a comparison with the fabrication method of the semiconductor device 100 according to the present embodiment, a fabrication method of the semiconductor device 101 according to a comparative example illustrated in FIG. 2 will be described. When the operational flow of the fabrication method of the semiconductor device 101 according to the comparative example is started by preparing the semiconductor wafer 10, similarly as in step S101 to step S103 of the operational flow of FIG. 1, the front surface structure is formed in the front surface 11 of the semiconductor wafer 10 (step S11), and the passivation film 120 is formed above the front surface structure (step S13).

In step S11, as an example, a resist 138 is provided above an electrode (not illustrated) provided in the front surface 11 of the semiconductor wafer 10. In step S13, the electrode (not illustrated) is patterned by forming the passivation film 120 above the front surface structure formed in the front surface 11 of the semiconductor wafer 10. Note that the front surface 11 of the semiconductor wafer 10 may be subjected to ion implantation, and the resist 138 may be a resist used for the ion implantation. The resist 138 may contain a photosensitive material.

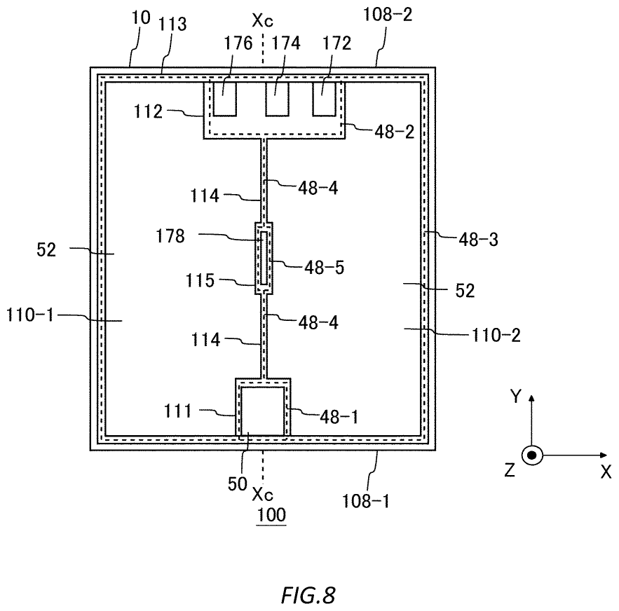

In step S11, as a specific example, the front surface structure of the RC-IGBT is formed on a low specific resistance p type silicon wafer, a main surface of which is (0 0 1) and which has a thickness of 725 μm. A field oxide film may be formed through thermal oxidation, a trench structure serving as a gate may be formed, and subsequently after this, a gate oxide film and gate polysilicon may be formed. A source n layer, an interlayer insulating film (BPSG), and a surface electrode may be formed. The passivation film 120 is formed above these front surface structure. The passivation film 120 may be provided above an emitter electrode 52 (see FIG. 8).

The passivation film 120 may be in contact with an upper surface of the emitter electrode 52. The passivation film 120 may be provided above the pad region. With the provision of the passivation film 120, the front surface 11 of the semiconductor wafer 10, the emitter electrode 52, and the pad region may be protected. Note that the emitter electrode 52, the pad region, and the like may be exposed in part from the passivation film 120. As an example, the passivation film 120 may be a protective film which becomes a polyimide film through thermal curing or may be a resist containing a photosensitive material.

To further protect the front surface 11 of the semiconductor wafer 10, the emitter electrode 52, and the pad region, thermal curing of the passivation film 120 may be performed. The thermal curing of the passivation film 120 may be implemented by a thermal treatment apparatus such as an annealing furnace, for example. The thermal curing of the passivation film 120 may be performed at a temperature T1. The treating time is one hour as an example. The temperature T1 is greater than or equal to 250 degrees and less than or equal to 400 degrees as an example and may be greater than or equal to 380 degrees and less than or equal to 400 degrees.

Similarly as in step S105 of the operational flow of FIG. 1, the protective film 130 is applied to the front surface 11 of the semiconductor wafer 10 (step S15). The application of the protective film 130 to the front surface 11 of the semiconductor wafer 10 may include applying the protective film 130 above the passivation film 120. The protective film 130 may be in contact with an upper surface of the passivation film 120. In the comparative example, the protective film 130 is a resist containing a photosensitive material as an example.

In step S15, the thermal curing of the protective film 130 may be performed to further protect the front surface 11 of the semiconductor wafer 10, the emitter electrode 52, and the pad region. The thermal curing of the protective film 130 may be implemented by a thermal treatment apparatus such as an annealing furnace, for example. The thermal curing of the protective film 130 may be performed at a temperature T2. The treating time is 30 minutes as an example. The temperature T2 is greater than or equal to 100 degrees and less than or equal to 200 degrees as an example.

A plurality of steps subsequent to step S15 in the operational flow of the fabrication method of the semiconductor device 101 according to the comparative example are different from a plurality of step subsequent step S105 in the operational flow of FIG. 1. According to the operational flow of the comparative example, in a state in which the protective film 130 is supported by a table or the like, for example, the back surface 12 of the semiconductor wafer 10 is ground by a grinding wheel of a grind apparatus such as a back grounder (BG) (step S17). FIG. 2 illustrates a shape of the semiconductor wafer 10 after the grinding. Since the protective film 130 formed above the passivation film 120 on the front surface 11 is supported by the table or the like without directly supporting the front surface 11 of the semiconductor wafer 10 by the table or the like, the front surface 11 of the semiconductor wafer 10, the emitter electrode 52, and the pad region are protected.

In step S17, in order to leave a ring-shaped reinforcement structure for the semiconductor wafer 10, an outer peripheral margin region 252 is formed in an outer circumference of the semiconductor wafer 10. That is, in step S17, an inner side of the outer peripheral margin region 252 is ground such that the outer peripheral margin region 252 is left in the outer circumference of the semiconductor wafer 10. A region of the semiconductor wafer 10 after the grinding on the inner side of the outer peripheral margin region 252 is set as a region 254. Since the outer peripheral margin region 252 is formed, warping of the semiconductor wafer 10 is suppressed to facilitate handing of the semiconductor wafer 10 in subsequent processes.

In the vacuum chamber, the back surface 12 of the semiconductor wafer 10 is processed in a state in which the protective film 130 is supported by the support stand 152. (step S19). In the backside processing in step S19, ion implantation into the region 254 of the back surface 12 is performed. As an example, a resist 140 is provided above the back surface 12 of the semiconductor wafer 10 to selectively perform the ion implantation into the back surface 12 of the semiconductor wafer 10, and subsequently a P type dopant such as boron or an N type dopant such as phosphorus is implanted into the back surface 12 of the semiconductor wafer 10. The resist 140 is a resist containing a photosensitive material as an example.

In step S19, since the protective film 130 formed above the passivation film 120 on the front surface 11 is supported by the support stand 152 without directly supporting the front surface 11 of the semiconductor wafer 10 by the support stand 152, the front surface 11 of the semiconductor wafer 10, the emitter electrode 52, and the pad region are protected.

The protective film 130 is taken off from the support stand 152 to remove the protective film 130 (step S21), and the operational flow ends. The protective film 130 may be removed by a chemical such as an organic solvent containing pyrrolidones, for example. The protective film 130 is not left in the semiconductor device 100.

In the operational flow of the fabrication method of the semiconductor device 101 according to the comparative example described above, the support stand 152 used in step S19 may also be referred to as a platen and also has a plurality of protruding portions in an upper surface 154 serving as a support surface and also has an annular protruding portion on an outer edge side of the upper surface 154. The support stand 152 chucks a support target while the support target is supported by edges of the plurality of protruding portions and an edge of the annular protruding portion. Since the support stand 152 has irregularities on an inner side of the annular protruding portion, when the semiconductor wafer 10 is supported, a space is formed between the semiconductor wafer 10 and recessed portions and the inner side of the annular protruding portion. In the support stand 152, to increase a cooling efficiency of the semiconductor wafer 10, a cooling gas may be caused to flow in the space in a state in which the semiconductor wafer 10 is supported. In this way, it is possible to increase an output of a beam current used when the ion implantation of the back surface 12 of the semiconductor wafer 10 is performed, and a back surface treating time can be shortened to improve a throughput of fabrication of the semiconductor device 101.

However, in the fabrication method of the semiconductor device 101 according to the comparative example, through the ion implantation into the back surface 12 of the semiconductor wafer 10, a large amount of gas 160 is generated from the protective film 130 to accumulate in the space as illustrated in FIG. 2. A phenomenon in which the gas 160 is generated is referred to as degassing herein. Since the gas accumulates in the irregularities due to the degassing, when the support stand 152 dechucks the semiconductor wafer 10 after step S19, an issue of bouncing of the semiconductor wafer 10 occurs. Even if the semiconductor wafer 10 is chucked by a table or the like which does not have a plurality of protruding portions instead of the support stand 152, since a large amount of gas 160 generated from the protective film 130 during the ion implantation into the back surface 12 of the semiconductor wafer 10 accumulates between the semiconductor wafer 10 and the table or the like, the issue of the bouncing of the semiconductor wafer 10 similarly occurs. When the dechucking is to be performed after a standby time is provided after the backside processing of the semiconductor wafer 10 to avoid the bouncing of the semiconductor wafer 10 described above, the throughput of the fabrication of the semiconductor device 101 is decreased corresponding to a duration of the standby time.

In addition, in the fabrication method of the semiconductor device 101 according to the comparative example, when the support stand 152 having the irregularities is used in step S19, as illustrated in FIG. 2, in step S19, biting of the protective film 130 made of a resist into the irregularities of the support stand 152 may be caused, and an issue may occur that it is unable to perform the dechucking since the semiconductor wafer 10 sticks to the support stand 152.

FIG. 3 is a diagram for describing the fabrication method of the semiconductor device 100 according to an embodiment. With reference to FIG. 3, a specific example of the operational flow illustrated in FIG. 1 will be described. Note that in FIG. 3, step S107 and step S109 described above are collectively illustrated.

In the operational flow of the fabrication method of the semiconductor device 100 according to the present embodiment, step S101 to step S105 described above may be similar to step S11 to step S15 in the operational flow of the comparative example illustrated in FIG. 2, and a duplicated description will be omitted. Note that in step S15 of the operational flow of the comparative example, the description has been provided where the protective film 130 may be heated to be cured, but in step S105, as being different from this, the protective film 130 is not cured by being heated. In step S105, low temperature bake may be performed to cause volatilization of a solvent in the protective film 130. This low temperature bake may be performed at a temperature that is greater than or equal to 80 degrees and less than or equal to 150 degrees. As described above, the protective film 130 may be a resist containing a photosensitive material or may be polyimide or the like having a high heat resistance than that of a resist. The protective film 130 of the present embodiment is polyimide as an example.

In step S105, the protective film 130 to be applied to the front surface 11 of the semiconductor wafer 10 may be thinner than the passivation film 120 of the front surface 11. A thickness of the protective film 130 is, for example, greater than or equal to 2 μm and less than or equal to 5 μm.

Laser annealing is performed, for example, in the backside processing in subsequent step S111, but as described above, the protective film 130 is required to leave in the front surface 11 of the semiconductor wafer 10 also during the backside processing too. Therefore, a glass transition temperature of the protective film 130 is, for example, greater than or equal to 200 degrees. A thermal decomposition temperature of the protective film 130 is, for example, greater than or equal to 300 degrees and less than or equal to 600 degrees.

As described above, the protective film 130 is patterned in step S107, and the protective film 130 is heated in step S109. In the present embodiment, the patterning of the protective film 130 may include forming a mask with a predetermined shape in the protective film 130 and etching the protective film 130 through exposure and development using the mask. The mask may be a photoresist. In step S109, a temperature at which the protective film 130 is heated to be cured, that is, a cure temperature of the protective film 130 may be, for example, approximately 250 degrees to 400 degrees. A thickness of the protective film 130 decreases by being cured. For example, the thickness of 5 μm before the curing decreases to the thickness of 4 μm after the curing.

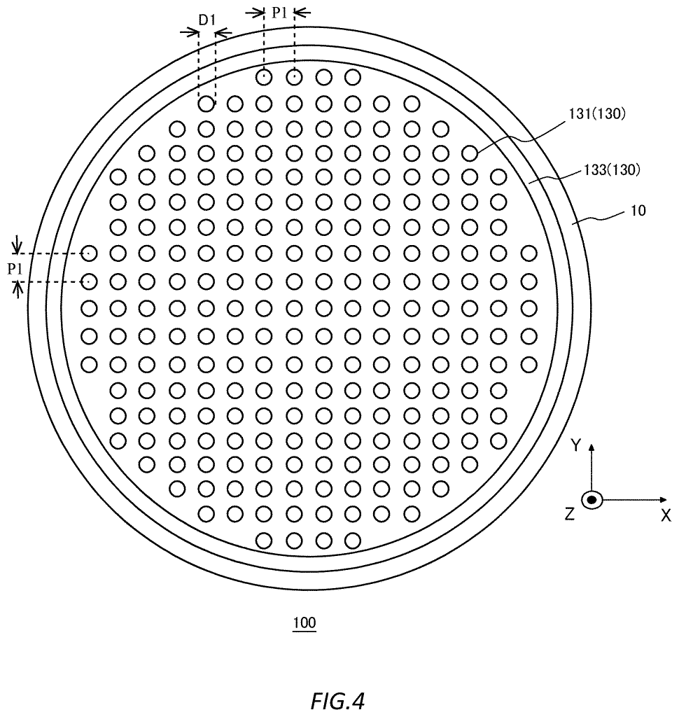

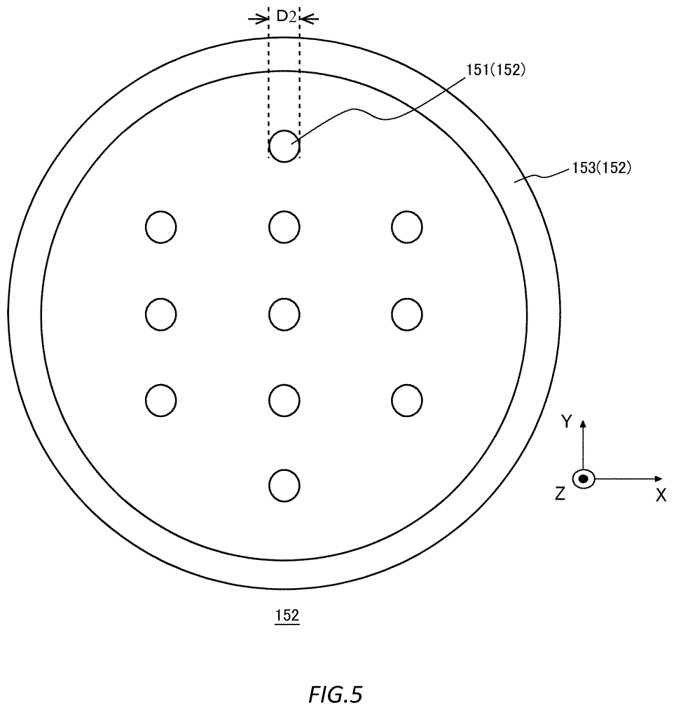

FIG. 4 is a plan view illustrating an example of the protective film 130 that is patterned of the front surface 11 of the semiconductor wafer 10 in the fabrication method of the semiconductor device 100 according to an embodiment. FIG. 5 is a plan view illustrating an example of a support stand which supports the protective film 130 that is patterned of the front surface 11 of the semiconductor wafer 10 in the fabrication method of the semiconductor device 100 according to an embodiment.

As illustrated in FIG. 5, as an example, the support stand 152 has a plurality of protruding portions 151 in a surface where the protective film 130 that is patterned of the front surface 11 of the semiconductor wafer 10 is held and also has an annular protruding portion 153 on an outer edge side of the surface. A shape in a top view of the protruding portions 151 as illustrated in FIG. 5, for example, may be circular, and in this case, a diameter of the circle, that is, a longest length D2 of the protruding portions 151 may be less than 1 mm. A pitch of the plurality of protruding portions 151 may be approximately 1 cm.

As illustrated in FIG. 4, as an example, the patterned protective film 130 has a plurality of protruding portions 131 and also has an annular protruding portion 133 which surrounds the plurality of protruding portions 131. A shape of the protruding portion 131 in a top view as illustrated in FIG. 4, for example, may be circular, and in this case, a diameter D1 of the circle may be the same as, or may be different from, a pitch P1 of the plurality of protruding portions 131. The diameter D1 of the circle may be greater than, or may be less than, the pitch P1 of the plurality of protruding portions 131. The diameter D1 of the circle may be greater than or equal to 3 μm and less than or equal to 0.2 mm. The pitch P1 of the plurality of protruding portions 131 may be greater than or equal to 20 μm and less than or equal to 0.3 mm.

The patterning of the protective film 130 in step S107 may include leaving the protective film 130 at the pitch P1 that is greater than or equal to 20 μm and less than or equal to 0.3 mm as in the plurality of protruding portions 131 illustrated in FIG. 4. The patterning of the protective film 130 may include leaving the protective film 130 in a manner that the longest length D1 of the pattern shape becomes greater than or equal to 3 μm and less than or equal to 0.2 mm as in the plurality of protruding portions 131 illustrated in FIG. 4.

The patterning of the protective film 130 may include leaving the protective film 130 in a manner that a protection rate of the front surface 11 by the protective film 130 becomes greater than or equal to 3% and less than or equal to 30%. The patterning of the protective film 130 may include forming an annular pattern corresponding to the annular protruding portion 153 of the support stand 152 illustrated in FIG. 5, for example, an annular protruding portion 133 in the front surface 11. The pitch P1 of the patterned protective film 130 may be less than the longest length D2 of the protruding portions 151 of the support stand 152 illustrated in FIG. 5. In this way, the protruding portions 151 of the support stand 152 are more likely to come into contact with the protective film 130.

Note that in the protective film 130 that is patterned in this manner, the front surface structure such as the emitter electrode and the pad region formed in the front surface 11 of the semiconductor wafer 10 can be prevented from coming into contact with the support stand 152. That is, the patterned protective film 130 can be prevented from being damaged since the front surface structure comes into contact with the support stand 152.

In step S111 of FIG. 3, in the vacuum chamber, the backside processing of the semiconductor wafer 10 is performed in a state in which the protective film 130 that is patterned of the front surface 11 is supported by the support stand 152, the protective film 130 is removed in step S113, and various protection film removal post-processes are performed in step S115 to end the operational flow. The backside processing of the semiconductor wafer 10 in step S111 may include performing backside processing of the semiconductor wafer 10 in a state in which the protective film 130 that is patterned is supported by the plurality of protruding portions 151 of the support stand 152. The backside processing of the semiconductor wafer 10 includes ion implantation into the back surface of the semiconductor wafer 10.

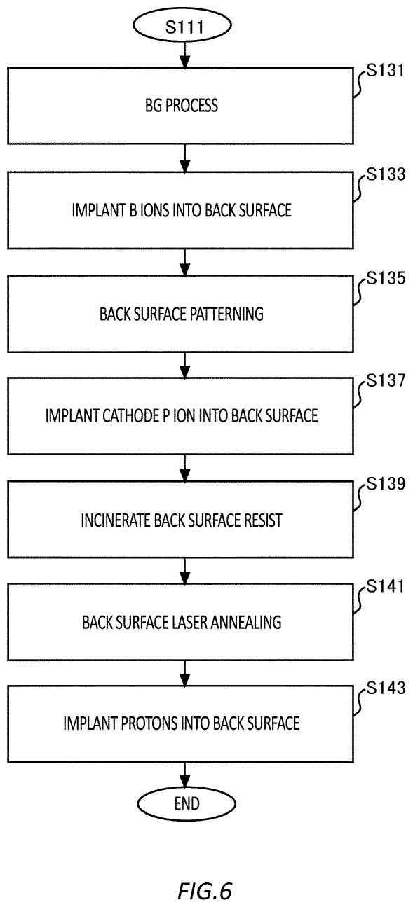

FIG. 6 is a flowchart representing an example of a subroutine of step S111 in the operational flow of FIG. 1. With reference to FIG. 6, a detail of step S111 in the fabrication method of the semiconductor device 100 including the RC-IGBT will be described.

According to step S111, for example, a BG process to grind the back surface 12 of the semiconductor wafer 10 is performed (step S131), B ions are implanted into the back surface 12 (step S133), patterning of the back surface 12 is performed by, for example, a photoresist (step S135), and cathode P ions are implanted into the back surface 12 (step S137). Furthermore, the resist of the back surface 12 is incinerated (step S139), laser annealing of the back surface 12 is performed (step S141), and protons are implanted into the back surface 12 (step S143) to end. In step S137, since the ion implantation is implemented into a cathode layer in only an FWD region, the back surface patterning is performed in step S135. In step S143, ion implantation of an FS layer may be implemented. In step S111, in at least step S133 and step S137, vacuum treatment of the back surface 12 is performed in the vacuum chamber. A rest of the processes in step S111 may be processed in a non-vacuum state.

Note that in the step of the ion implantation into the back surface 12, P+ may be implanted when the semiconductor device 100 includes an IGBT, P+ may be put into the entire surface when the semiconductor device 100 includes an RC-IGBT to turn to N+, N+ may be implanted when the semiconductor device 100 includes an MOSFET, and N+ may be implanted when the semiconductor device 100 includes an FWD.

With regard to the laser annealing in step S141, when the protective film 130 is made of a high heat resistance protective film such as polyimide having a higher heat resistance than that of a resist, a laser oscillation period of the laser annealing may be shortened as compared to a case where the resist is adopted. Even when the laser output is increased during the laser annealing processing, the high heat resistance protective film does not alter in quality like the resist, and a situation is not established where the support stand 152 or the like is contaminated or it becomes difficult to perform delamination of the protective film 130 from the support stand 152. For example, the laser output may be increased from 1 kHz to 3 kHz to shorten the laser oscillation period to one third. In this way, the back surface treating time can be shortened to improve the throughput of the fabrication of the semiconductor device 100 by approximately two times.

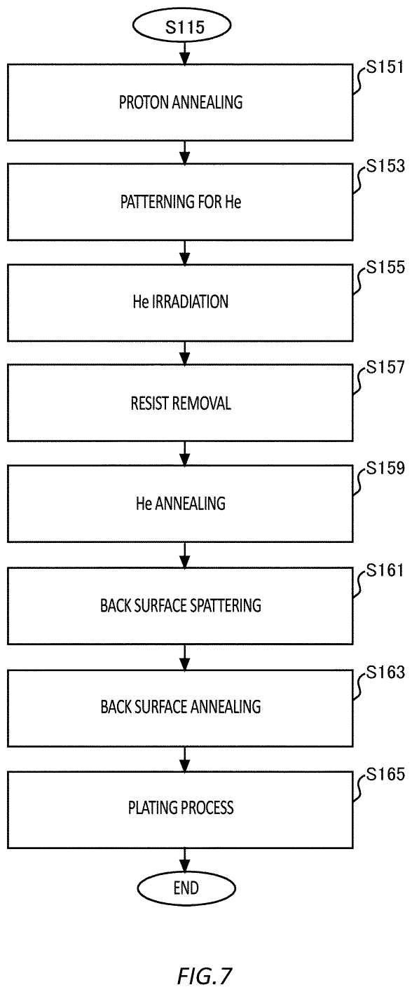

FIG. 7 is a flowchart representing an example of a subroutine of step S115 in the operational flow of FIG. 1. With reference to FIG. 7, a detail of step S115 in the fabrication method of the semiconductor device 100 including the RC-IGBT will be described.

According to step S115, for example, proton annealing of the front surface 11 of the semiconductor wafer 10 is performed (step S151), patterning for He is performed on the front surface 11 by the resist (step S153), He irradiation is performed (step S155), and the resist is removed (step S157). Furthermore, He annealing is performed (step S159), spattering of the back surface 12 is performed (step S161), annealing of the back surface 12 is performed (step S163), and a plating process is performed (step S165) to end. After the protective film 130 is removed through dissolution delamination or the like in step S113, to activate ions implanted into the FS layer, an anneal process may be implemented in step S151. Subsequently, a back surface electrode may be formed in step S165 to complete a wafer process. In step S115, the vacuum treatment of the back surface 12 is performed in the vacuum chamber in at least step S161, but a degree of vacuum is weaker than that in step S111. Note that in the backside processing in step S161 or the like which falls within step S115, the support stand 152 is not used, and the front surface structure in the front surface 11 is not to be damaged.

In accordance with the fabrication method of the semiconductor device 100 according to the present embodiment described above, the protective film 130 is applied to the front surface 11 of the semiconductor wafer 10, the protective film 130 is patterned, in the vacuum chamber, the backside processing of the semiconductor wafer 10 is performed in a state in which the protective film 130 that is patterned of the front surface 11 is supported by the support stand 152, and subsequently, the protective film 130 is removed. In accordance with the fabrication method of the semiconductor device 100 according to the present embodiment, a degassing amount during the backside processing can be reduced as compared to a case where the backside processing is performed without patterning the protective film 130, that is, a case where the backside processing is performed without reducing a volume of the protective film 130 applied to the front surface 11. In this way, a measure to avoid the bouncing of the semiconductor wafer 10 like the fabrication method of the semiconductor device 101 according to the comparative example becomes unnecessary, and the decrease in the throughput of the fabrication of the semiconductor device 100 can be prevented.

An effect of the above by reducing the volume by patterning the protective film 130 may be remarkable in particular when polyimide is adopted as the protective film 130. Since polyimide has a higher elastic modulus than a resist, biting into the irregularities of the support stand 152 hardly occurs, and as described above, it is possible to increase the laser output during the laser annealing process of the back surface 12. However, since polyimide has a higher moisture absorption than the resist, moisture evaporates from a polyimide film during the ion implantation into the back surface 12, that is, the degassing amount increases. Note that as described above, a material of the protective film 130 is not limited to polyimide. Such a material of the protective film 130 may be preferable that the biting into the irregularities of the support stand 152 during the ion implantation into the back surface 12 hardly occurs, it is possible to perform the patterning for reducing an influence of the degassing, and a process similar to the process described above becomes possible.

FIG. 8 illustrates an example of a positioning of a gate runner 48, a well region, and a pad region of the semiconductor device 100 in a top view. The semiconductor device 100 illustrated in FIG. 8 may be one of a plurality of pieces fabricated by dicing the semiconductor wafer 10 fabricated by the fabrication method illustrated in FIG. 3. The semiconductor wafer 10 has an end side 108 in a top view. The semiconductor wafer 10 of the present example has two pairs of end sides 108 facing each other in a top view. In FIG. 8, a pair of end side 108-1 and an end side 108-2 facing each other is illustrated. In FIG. 8, a direction parallel to the end side 108-1 and the end side 108-2 is referred to as an X axis direction, and a direction perpendicular to the end side 108-1 and the end side 108-2 is referred to as a Y axis direction.

The semiconductor wafer 10 is provided with an active section 110. In the present example, the semiconductor wafer 10 is provided with an active section 110-1 and an active section 110-2. The active section 110 is a region in which a main current flows in the depth direction between an upper surface and a lower surface of the semiconductor wafer 10 when the semiconductor device 100 is controlled to be put into an ON state. Accordingly, a region on an inner side of a well region in FIG. 8 may be referred to as the active section 110. The active section 110 may be provided with a transistor portion including a transistor device such as an IGBT. The active section 110 may be provided with a diode portion including a diode device such as a FWD. The active section 110 may be a region in which at least one of the transistor portion or the diode portion is provided. As described in FIG. 8, in the present example, the active section 110 is provided with the transistor portion and the diode portion. The active section 110 may be a region which overlaps with an upper surface main electrode in a top view. The upper surface main electrode may be an electrode with a largest area in a top view among electrodes positioned above the upper surface of the semiconductor wafer 10. The upper surface main electrode may be electrically connected to an emitter region or a source region of the transistor portion or may be electrically connected to an anode region of the diode portion, for example. In the example of FIG. 8, the emitter electrode 52 is the upper surface main electrode.

The semiconductor wafer 10 is provided with a P type well region. The well region is a P type region having a higher concentration than a base region of the transistor portion or the anode region of the diode portion. The base region is a P type region which is positioned opposite to a gate electrode and which has a channel formed in a portion opposite to the gate electrode when a predetermined gate voltage is applied to the gate electrode. The semiconductor device 100 has a first well region 111 and a second well region 112. The first well region 111 and the second well region 112 are positioned to sandwich the active section 110 in a top view. The first well region 111 and the second well region 112 are positioned to sandwich the active section 110 in a predetermined direction (Y axis direction in FIG. 8). The sandwiching of the active section 110 by the two well regions refers to that any straight line connecting the two well regions in a top view passes through the active section 110.

The first well region 111 may be positioned in vicinity of the end side 108-1. That is, a distance between the first well region 111 and the end side 108-1 is smaller than a distance between the first well region 111 and the end side 108-2. The second well region 112 may be positioned in vicinity of the end side 108-2. That is, a distance between the second well region 112 and the end side 108-2 is smaller than a distance between the second well region 112 and the end side 108-1.

The first well region 111 of the present example is positioned in the Y axis direction between the active section 110 and the end side 108-1. The active section 110 is not provided between the first well region 111 and the end side 108-1. That is, the first well region 111 is positioned between the end portion of the active section 110 in the Y axis direction and the end side 108-1.

The second well region 112 of the present example is positioned in the Y axis direction between the active section 110 and the end side 108-2. The active section 110 is not provided between the second well region 112 and the end side 108-2. That is, the second well region 112 is positioned between the end portion of the active section 110 in the Y axis direction and the end side 108-2.

The first well region 111 and the second well region 112 may be provided, in the X axis direction, in a range including a center position Xc of the end side 108-1 and the end side 108-2. The first well region 111 may be sandwiched between the active sections 110 in the X axis direction. The second well region 112 may be sandwiched between the active sections 110 in the X axis direction. The second well region 112 may be provided in a wider range in the X axis direction than the first well region 111.

The semiconductor device 100 may have a peripheral well region 113 positioned to surround the active section 110 in a top view. The peripheral well region 113 may be provided to be parallel to each of the end sides of the semiconductor wafer 10. The peripheral well region 113 of the present example is an annular region surrounding the active section 110 in a top view. The peripheral well region 113 may have a constant width in a direction perpendicular to each of the end sides.

The first well region 111 and the second well region 112 of the present example protrude closer to a central side of the active section 110 than the peripheral well region 113. In another example, at least one of the first well region 111 or the second well region 112 may be positioned between the peripheral well region 113 and the end side 108 of the semiconductor wafer 10. In this case, the first well region 111 and the second well region 112 protrude from the peripheral well region 113 to the end side 108 side.

The semiconductor device 100 may have a dividing well region 114 for dividing the active section 110 in a top view. Because of a well region including the dividing well region 114, the active section 110 may be divided into the active section 110-1 and the active section 110-2. The dividing well region 114 has a longitudinal part in a predetermined well longitudinal direction. The dividing well region 114 extends in the well longitudinal direction to traverse the active section 110. The well longitudinal direction of the dividing well region 114 is the Y axis direction.

The dividing well region 114 may be provided between the first well region 111 and the second well region 112. One end in the longitudinal direction of the dividing well region 114 may be connected to the first well region 111, and another end may be connected to the second well region 112. The dividing well region 114 may be provided in a region which overlaps with a center of the active section 110.

The dividing well region 114 may include a wide portion 115 whose width in a direction perpendicular to the well longitudinal direction in a top view (in the present example, X axis direction) is wider than those of the other portions. The wide portion 115 is also provided between the first well region 111 and the second well region 112. The wide portion 115 may be provided in a region which overlaps with a center of the active section 110. The wide portion 115 may be positioned in a region including a center in the well longitudinal direction of the dividing well region 114.

The semiconductor device 100 of the present example has a control electrode such as a gate pad 50, a current detection pad 172, an anode pad 174, and a cathode pad 176. Each of the gate pad 50, the current detection pad 172, the anode pad 174, and the cathode pad 176 is an example of the pad region.

A temperature sensing unit 178 is a PN junction diode formed of a semiconductor material such as polysilicon. The temperature sensing unit 178 is positioned above the wide portion 115. That is, at least part of the temperature sensing unit 178 and at least part of the wide portion 115 are overlapped. A region occupying half or more of the temperature sensing unit 178 of the present example in a top view is overlapped with the wide portion 115. The temperature sensing unit 178 may overlap with the wide portion 115 as a whole.

The emitter electrode 52 and each of the control electrodes are electrodes containing metal such as aluminum. An insulating film is provided between the emitter electrode 52 and each of the control electrodes and the semiconductor wafer 10. The emitter electrode 52 and each of the control electrodes and the semiconductor wafer 10 are connected via a contact hole provided in the insulating film. In FIG. 8, the insulating film and the contact hole are omitted.

The emitter electrode 52 is positioned above the active section 110. The emitter electrode 52 is connected to the active section 110 via the contact hole described above. A wiring member is connected to the upper surface of the emitter electrode 52, and a predetermined emitter voltage is applied thereto. The emitter electrode 52 and each of the control electrodes are provided separately from each other in a top view. A wire or the like is connected to an upper surface of each of the control electrodes. The emitter electrode 52 may be provided for each of the active section 110-1 and the active section 110-2.

A predetermined gate voltage is applied to the gate pad 50. The gate voltage applied to the gate pad 50 is supplied to the transistor portion of the active section 110 by a gate runner or the like described below. The gate pad 50 is positioned above the first well region 111. That is, at least part of the gate pad 50 and at least part of the first well region 111 are overlapped. A region occupying half or more of the gate pad 50 of the present example in a top view is overlapped with the first well region 111. The gate pad 50 may overlap with the first well region 111 as a whole. The gate pad 50 of the present example may be positioned in vicinity of the end side 108-1 of the semiconductor device 100. That is, the gate pad 50 is positioned between the emitter electrode 52 and the end side 108-1 of the semiconductor device 100, and the emitter electrode 52 is not positioned between the gate pad 50 and the end side 108-1. Furthermore, the gate pad 50 may be positioned in a region including the center position Xc in the X axis direction of the end side 108-1 of the semiconductor device 100.

The current detection pad 172 is connected to a current detection unit (not illustrated) and detects a current flowing in the current detection unit. The anode pad 174 is connected to an anode region of the temperature sensing unit 178 via a wiring. The cathode pad 176 is connected to a cathode region of the temperature sensing unit 178 via a wiring. The current detection pad 172, the anode pad 174, and the cathode pad 176 are positioned above the second well region 112. For the respective control electrodes of the current detection pad 172, the anode pad 174, and the cathode pad 176, at least part of the control electrode overlaps with at least part of the second well region 112. Regions occupying half or more of the current detection pad 172, the anode pad 174, and the cathode pad 176 of the present example in a top view overlap with the second well region 112. The current detection pad 172, the anode pad 174, and the cathode pad 176 may overlap with the second well region 112 as a whole. The respective control electrodes of the current detection pad 172, the anode pad 174, and the cathode pad 176 of the present example may be positioned in vicinity of the end side 108-2 of the semiconductor device 100. That is, the respective control electrodes of the current detection pad 172, the anode pad 174, and the cathode pad 176 are positioned between the emitter electrode 52 and the end side 108-2 of the semiconductor device 100, but the emitter electrode 52 is not positioned between the respective control electrodes and the end side 108-2. Furthermore, the respective control electrodes may be positioned in a region including the center position Xc in the X axis direction of the end side 108-2 of the semiconductor device 100. In the present example, the gate pad 50, as well as the respective control electrodes of the current detection pad 172, the anode pad 174, and the cathode pad 176 may be respectively positioned in the end side 108-1 and 108-2 of the semiconductor device 100 which are facing each other. Furthermore, they may be positioned to face each other via the dividing well region 114.

In FIG. 8, the gate runner 48 is represented by a dashed line. The gate runner 48 is a wiring formed of polysilicon with impurity added thereto or a conductive material such as metal. The gate runner 48 supplies, to the transistor portion provided in the active section 110, a gate voltage applied to the gate pad 50. The gate runner 48 may be positioned above the well region.

The semiconductor device 100 may have a gate runner 48-3 positioned to surround the active section 110 in a top view. The gate runner 48-3 may be positioned above the peripheral well region 113.

The semiconductor device 100 may include a gate runner 48-1 which surrounds at least a partial region of the first well region 111 in a top view. The gate runner 48-1 may be positioned along end sides of the first well region 111 in a top view. The gate runner 48-1 may include portions parallel to each of the end sides of the first well region 111.

The semiconductor device 100 may include a gate runner 48-2 which surrounds at least a partial region of the second well region 112 in a top view. The gate runner 48-2 may be positioned along an end side of the second well region 112 in a top view. The gate runner 48-2 may include portions parallel to each of the end sides of the second well region 112.

The semiconductor device 100 may have a gate runner 48-4 positioned above the dividing well region 114 in a top view. The semiconductor device 100 may include a gate runner 48-5 which surrounds at least a partial region of the wide portion 115 in a top view. The gate runner 48-5 may be positioned along an end side of the wide portion 115 in a top view. The gate runner 48-5 may have portions parallel to each of the end sides of the wide portion 115. The gate runner 48-4 and the gate runner 48-5 may divide the active section 110 in a top view.

The semiconductor device 100 may include an edge termination structure portion between the peripheral well region 113 and the end side of the semiconductor wafer 10. The edge termination structure portion relaxes an electric field strength on an upper surface side of the semiconductor wafer 10. The edge termination structure portion is structured by, for example, a guard ring provided in an annular shape surrounding the active section 110, a field plate, a Resurf, and a combination thereof.

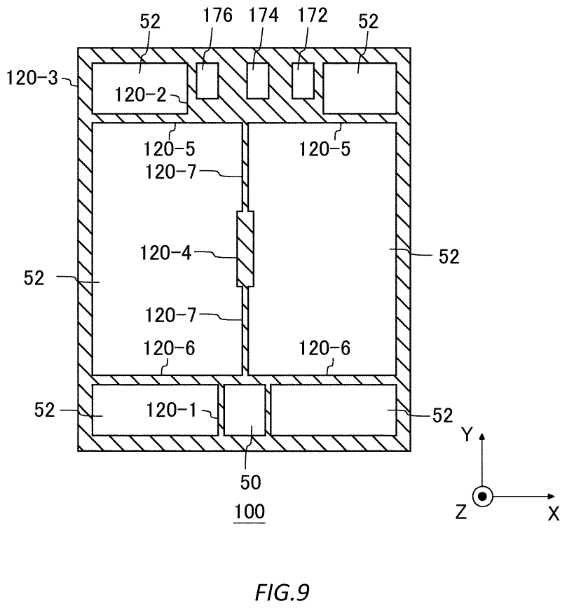

FIG. 9 illustrates an example of a positioning of the passivation film 120 of the semiconductor device 100 in a top view. In FIG. 9, a region where the passivation film 120 is positioned is indicated by diagonal hatching.

The semiconductor device 100 may have a passivation film 120-1 which covers the first well region 111. The passivation film 120-1 may expose part of an upper surface of the gate pad 50. In this way, a wire or the like can be connected to the upper surface of the gate pad 50.

The semiconductor device 100 may have a passivation film 120-2 which covers the second well region 112. The passivation film 120-2 may expose part of upper surfaces of the current detection pad 172, the anode pad 174, and the cathode pad 176. In this way, a wire or the like can be connected to the upper surfaces of the current detection pad 172, the anode pad 174, and the cathode pad 176.

The semiconductor device 100 may have a passivation film 120-3 which covers the peripheral well region 113. The passivation film 120-3 may cover the entire peripheral well region 113. The semiconductor device 100 may have a passivation film 120-4 and a passivation film 120-7 which cover the dividing well region 114. The entire dividing well region 114 may be covered with the passivation film 120-4 and the passivation film 120-7. In the present example, the passivation film 120-4 covers an entire wide portion 115, and the passivation film 120-7 covers the entire dividing well region 114 other than the wide portion 115.

The passivation film 120 exposes part of the upper surface of the emitter electrode 52. In this way, a wire or the like can be easily connected to the upper surface of the emitter electrode 52.

The semiconductor device 100 may have a passivation film 120-5 and a passivation film 120-6 which divide the upper surface of the semiconductor wafer 10. The passivation film 120-5 and the passivation film 120-6 may be provided across the upper surface of the semiconductor wafer 10 in the X axis direction.

To summarize the above, the passivation film 120 is not entirely provided in the semiconductor wafer 10 above the semiconductor wafer 10. That is, a predetermined pattern is formed in the passivation film 120. The passivation film 120 exposes part of the upper surface of the emitter electrode 52 and part of the pad or the like.

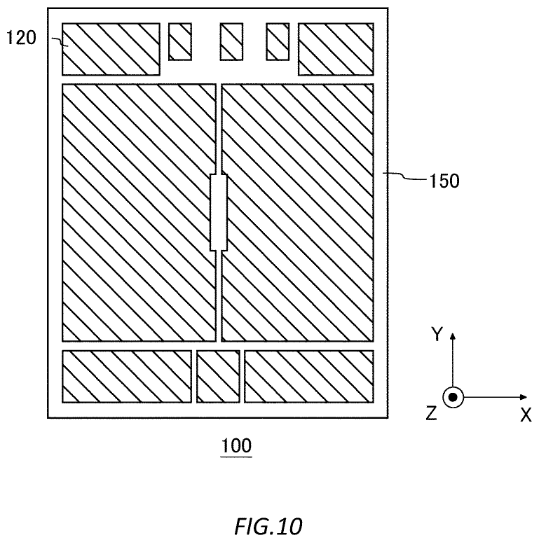

FIG. 10 illustrates an example of a positioning of the resist 150 used when the passivation film 120 is patterned. The resist 150 covers the passivation film 120-1, the passivation film 120-2, the passivation film 120-3, the passivation film 120-4, the passivation film 120-5, the passivation film 120-6, and the passivation film 120-7 of FIG. 9. Accordingly, the predetermined pattern as illustrated in FIG. 9 can be formed in the passivation film 120. The passivation film 120 that is not covered by the resist 150 is removed. A photosensitive material may be contained in the resist 150.

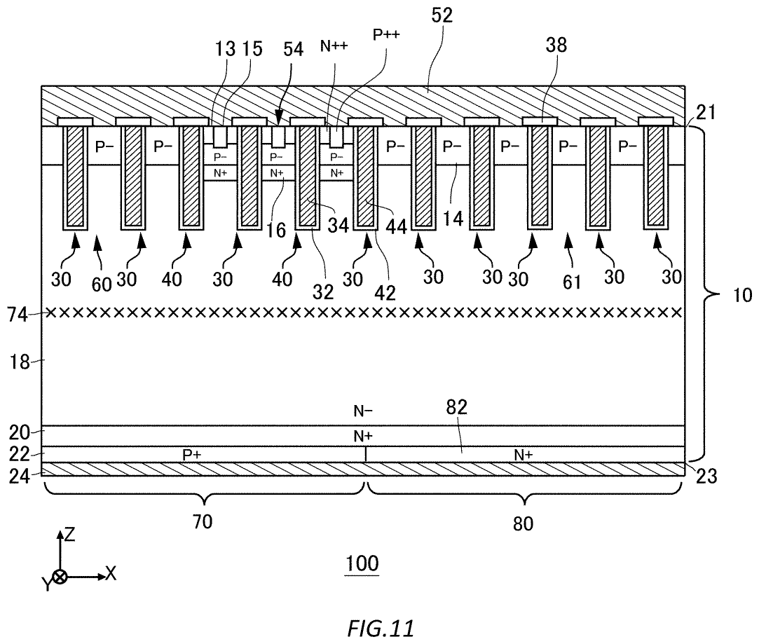

FIG. 11 illustrates an example of a cross section of the semiconductor device 100 in the active section 110. This cross section is an XZ plane which passes through an emitter region 13 and a cathode region 82. The semiconductor device 100 of the present example includes the semiconductor wafer 10, an interlayer insulating film 38, the emitter electrode 52, and a collector electrode 24 in the cross section.

The transistor portion 70 includes a P+ type collector region 22 in a region in contact with the lower surface of the semiconductor wafer 10. In the transistor portion 70, on the upper surface side of the semiconductor wafer 10, a gate structure having the N type emitter region 13, a P type base region 14, a contact region 15, a gate conductive portion, and a gate insulating film is periodically positioned.

A diode portion 80 has an N+ type cathode region 82 in a region in contact with the lower surface of the semiconductor wafer 10. In the present specification, a region where the cathode region is provided is referred to as the diode portion 80. In other words, the diode portion 80 is a region that overlaps with the cathode region in the top view. In the lower surface of the semiconductor wafer 10, in a region other than the cathode region, a P+ type collector region may be provided.

The interlayer insulating film 38 is provided in the upper surface of the semiconductor wafer 10. The interlayer insulating film 38 is a film including at least one layer of an insulating film such as silicate glass to which an impurity such as boron or phosphorus is added, a thermal oxide film, or other insulating films. The interlayer insulating film 38 is provided with a contact hole 54.

The emitter electrode 52 is provided above the interlayer insulating film 38. The emitter electrode 52 is in contact with an upper surface 21 of the semiconductor wafer 10 through a contact hole 54 of the interlayer insulating film 38. The collector electrode 24 is provided in a lower surface 23 of the semiconductor wafer 10. The collector electrode 24 is formed of a metal material such as aluminum.

Each of the transistor portion 70 and the diode portion 80 has a plurality of trench portion arranged in an arrangement direction (In the present example, X axis direction). In the transistor portion 70 of the present example, one or more gate trench portions 40 and one or more dummy trench portions 30 are periodically provided along the arrangement direction. In the diode portion 80 of the present example, the plurality of dummy trench portions 30 are provided along the arrangement direction. In the diode portion 80 of the present example, a gate trench portion 40 is not provided.

A mesa portion is provided between each of the trench portions in the arrangement direction. The mesa portion refers to a region sandwiched by the trench portions inside the semiconductor wafer 10. An upper end of the mesa portion is the upper surface of the semiconductor wafer 10 as an example. A depth position of a lower end of the mesa portion is the same as a depth position of a lower end of the trench portion. The mesa portion of the present example is provided which extends in an extending direction (Y axis direction) along a trench in the upper surface of the semiconductor wafer 10. In the present example, a mesa portion 60 is provided in the transistor portion 70, and a mesa portion 61 is provided in the diode portion 80. In the case of simply mentioning “mesa portion” in the present specification, the portion refers to each of the mesa portion 60 and the mesa portion 61.

Each of the mesa portions is provided with the base region 14. The mesa portion 60 of the transistor portion 70 has the emitter region 13 exposed in the upper surface 21 of the semiconductor wafer 10. The emitter region 13 is provided in contact with the gate trench portion 40. The mesa portion 60 in contact with gate trench portion 40 may be provided with the contact region 15 exposed in the upper surface 21 of the semiconductor wafer 10.

As an example, the contact region and the emitter region 13 of the mesa portion 60 are provided in a stripe-like shape along the extending direction (Y axis direction) of the trench portion. That is, the emitter regions 13 are provided in a region in contact with the trench portion, and the contact region 15 is provided in a region sandwiched by the emitter regions 13.

In another example, the contact region 15 and the emitter region 13 of the mesa portion 60 are each provided from one trench portion to the other trench portion in the X axis direction. In this case, the contact region 15 and the emitter region 13 of the mesa portion 60 may be positioned alternately along the extending direction (Y axis direction) of the trench portion.

The emitter region 13 is not provided in the mesa portion 61 of the diode portion 80. The base region 14 and the contact region 15 may be provided in the upper surface of the mesa portion 61.

An accumulation region 16 is provided below the base region 14. The accumulation region 16 is an N+ type region having a higher doping concentration than a drift region 18. By providing the high concentration accumulation region 16 between the drift region 18 and the base region 14, a carrier injection enhancement effect (IE effect) can be enhanced, and an ON voltage can be reduced. The accumulation region 16 may be provided to cover the entire lower surface of the base region 14 on each of the mesa portions 60. The accumulation region 16 may be provided on the transistor portion 70 only.

On each of the transistor portion 70 and the diode portion 80, an N+ type buffer region 20 is provided on a side closer to the lower surface 23 than the drift region 18. The buffer region 20 may function as a field stop layer which prevents a depletion layer expanding from the lower end of the base region 14 from reaching the P+ type collector region 22 and the N+ type cathode region 82.

In the transistor portion 70, the P+ type collector region 22 is provided below the buffer region 20. The acceptor concentration of the collector region 22 is higher than the acceptor concentration of the base region 14. The collector region 22 may include the same acceptor as the base region 14, and may include a different acceptor. The acceptor of the collector region 22 is, for example, boron.

In the diode portion 80, the N+ type cathode region 82 is provided below the buffer region 20. The donor of the cathode region 82 is, for example, hydrogen or phosphorus. Note that an element serving as a donor and an acceptor in each region is not limited to the examples described above.

One or more gate trench portions 40 and one or more dummy trench portions 30 are provided on an upper surface 21 side of the semiconductor wafer 10. Each of the trench portions penetrates the base region 14 from the upper surface 21 of the semiconductor wafer 10 to reach the drift region 18. A configuration in which a trench portion penetrates a doped region is not limited to a configuration which is fabricated by forming a doped region and forming a trench portion in this order. The configuration of the trench portions penetrating the doped region also includes a configuration of forming the trench portions and then forming the doped region between the trench portions.

The gate trench portion 40 has a gate trench provided in the upper surface 21 of the semiconductor wafer 10, a gate insulating film 42, and a gate conductive portion 44. The gate insulating film 42 is provided to cover an inner wall of the gate trench. The gate insulating film 42 may be formed by oxidizing or nitriding a semiconductor at the inner wall of the gate trench. The gate conductive portion 44 is provided farther inward than the gate insulating film 42 inside the gate trench. That is, the gate insulating film 42 insulates the gate conductive portion 44 from the semiconductor wafer 10. The gate conductive portion 44 is formed of a conductive material such as polysilicon.

The gate conductive portion 44 may be provided to be longer than the base region 14 in the depth direction. The gate trench portion 40 in the cross section is covered by the interlayer insulating film 38 in the upper surface 21 of the semiconductor wafer 10. The gate conductive portion 44 is electrically connected to the gate runner 48. The gate conductive portion 44 may be connected to the gate pad 50. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 has a dummy trench provided in the upper surface 21 of the semiconductor wafer 10, a dummy insulating film 32, and a dummy conductive portion 34. The dummy conductive portion 34 may be connected to an electrode different from the gate pad 50. For example, the dummy conductive portion 34 may be connected to a dummy pad which is not illustrated and which is connected to an external circuit different from the gate pad 50, and a control different from that of the gate conductive portion 44 may be performed. In addition, the dummy conductive portion 34 may be electrically connected to the emitter electrode 52. The dummy insulating film 32 is provided to cover an inner wall of the dummy trench. The dummy conductive portion 34 is provided inside the dummy trench and is provided farther inward than the dummy insulating film 32. The dummy insulating film 32 insulates the dummy conductive portion 34 from the semiconductor wafer 10. The dummy conductive portion 34 may be formed of a same material as the gate conductive portion 44. For example, the dummy conductive portion 34 is formed of a conductive material such as polysilicon. The dummy conductive portion 34 may have a same length as the gate conductive portion 44 in the depth direction.

The gate trench portion 40 and the dummy trench portion 30 of the present example are covered with the interlayer insulating film 38 in the upper surface 21 of the semiconductor wafer 10. Note that bottom portions of the dummy trench portion 30 and the gate trench portion 40 may be formed in a curved-surface shape (a curved shape in the cross section) convexly downward.

A lifetime control unit 74 is a region where a lifetime killer is intentionally formed by, for example, implanting impurities into the inside of the semiconductor substrate. The lifetime killer is a recombination center of carriers and may be a crystal defect or may be a vacancy, a divacancy, a defect complex of these with an element constituting the semiconductor wafer 10, a dislocation, a rare gas element such as helium or neon, a metal element such as platinum, or the like. The lifetime control unit 74 can be formed by implanting helium or the like into the semiconductor wafer 10.

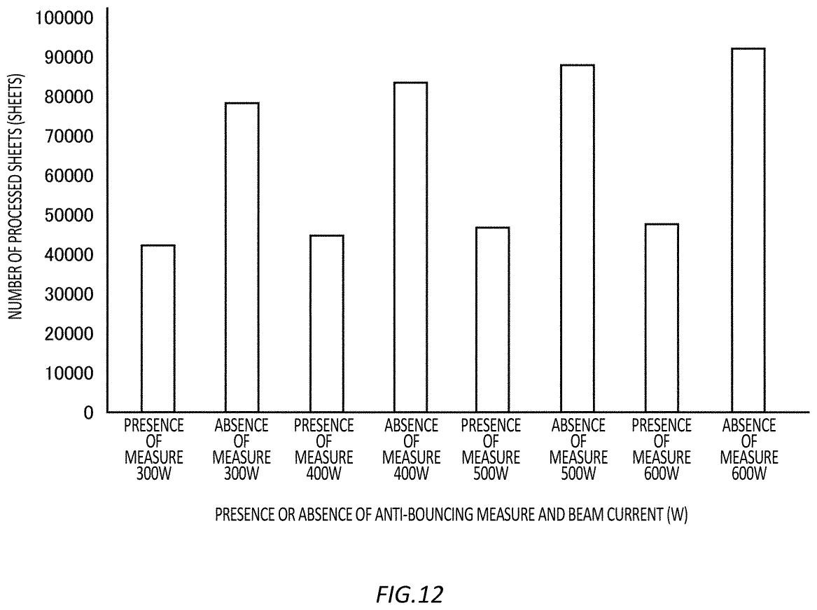

FIG. 12 illustrates a relationship between the presence or absence of an anti-bouncing measure and a beam current, and a number of processed sheets. The anti-bouncing measure refers to dechucking to be performed after a standby time is provided as in the comparative example illustrated in FIG. 2. The beam current is an output of the beam current during the ion implantation.

In FIG. 12, when the beam currents are the same, the number of processed sheets is greater in a case where the anti-bouncing measure is not taken compared to a case where the the anti-bouncing measure is taken. It is because a standby time is provided for dechucking in a case where the anti-bouncing measure is taken, and more time for processing is therefore required. Since the degassing amount of the patterned protective film 130 in the fabrication method of the semiconductor device 100 according to the present embodiment is lower than the degassing amount of the protective film 130 that is not patterned in the fabrication method of the semiconductor device 101 according to the comparative example, it is not required to implement the anti-bouncing measure, and the throughput can be improved.

In addition, by increasing the output of the beam current during the ion implantation, the number of processed sheets can be increased. Since the support stand 152 has the irregularities in the upper surface 154 in the present embodiment, a cooling gas can be caused to flow between the semiconductor wafer 10 and the support stand, and the output of the beam current during the ion implantation can be increased.

While the embodiments of the present invention have been described, the technical scope of the present invention is not limited to the above-described embodiments. It is apparent to persons skilled in the art that various alterations and improvements can be added to the above-described embodiments. It is also apparent from the scope of the claims that the embodiments added with such alterations or improvements can be included in the technical scope of the present invention.

It should be noted that the operations, procedures, steps, stages, and the like of each process performed by an apparatus, system, program, and method illustrated in the claims, the specification, or the drawings can be realized in any order as long as the order is not indicated by “prior to,” “before,” or the like and as long as the output from a previous process is not used in a later process. Even if the operational flow is described by using phrases such as “first” or “next” for the sake of convenience in the claims, specification, and drawings, it does not necessarily mean that the process must be performed in this order.

### EXPLANATION OF REFERENCES

10: semiconductor wafer;
11: front surface;
12: back surface;
13: emitter region;
14: base region;
15: contact region;
16: accumulation region;
18: drift region;
20: buffer region;
21: upper surface;
22: collector region;
23: lower surface;
24: collector electrode;
30: dummy trench portion;
32: dummy insulating film;
34: dummy conductive portion;
38: interlayer insulating film;
40: gate trench portion;
42: gate insulating film;
44: gate conductive portion;
48: gate runner;
50: gate pad;
52: emitter electrode;
54: contact hole;
60: mesa portion;
61: mesa portion;
70: transistor portion;
74: lifetime control unit;
80: diode portion;
82: cathode region;
100, 101: semiconductor device;
108: end side;
110: active section;
111: first well region;
112: second well region;
113: peripheral well region;
114: dividing well region;
115: wide portion;
120: passivation film;
130: protective film;
131: protruding portion;
133: annular protruding portion;
138: resist;
140: resist;
152: support stand;
151: protruding portion;
153: annular protruding portion;
154: upper surface;
160: gas;
172: current detection pad;
174: anode pad;
176: cathode pad;
178: temperature sensing unit;
252: outer peripheral margin region; and
254: region.

What is claimed is:

1. A fabrication method of a semiconductor device, the fabrication method comprising:
applying a protective film to a front surface of a semiconductor wafer;
patterning the protective film;
performing backside processing of the semiconductor wafer in a state in which the protective film that is patterned of the front surface is supported by a support stand in a vacuum chamber; and
removing the protective film after the backside processing of the semiconductor wafer is performed.

2. The fabrication method of the semiconductor device according to claim 1, wherein
the performing the backside processing includes performing ion implantation into a back surface of the semiconductor wafer.

3. The fabrication method of the semiconductor device according to claim 1, wherein
the protective film is polyimide.

4. The fabrication method of the semiconductor device according to claim 2, wherein
the protective film is polyimide.

5. The fabrication method of the semiconductor device according to claim 1, the fabrication method further comprising:
forming a front surface structure in the front surface of the semiconductor wafer; and
forming a passivation film above the front surface structure, wherein
the applying the protective film to the front surface of the semiconductor wafer includes applying the protective film above the passivation film, and
the protective film is thinner than the passivation film.

6. The fabrication method of the semiconductor device according to claim 2, the fabrication method further comprising:
forming a front surface structure in the front surface of the semiconductor wafer; and
forming a passivation film above the front surface structure, wherein
the applying the protective film to the front surface of the semiconductor wafer includes applying the protective film above the passivation film, and
the protective film is thinner than the passivation film.

7. The fabrication method of the semiconductor device according to claim 3, the fabrication method further comprising:
forming a front surface structure in the front surface of the semiconductor wafer; and
forming a passivation film above the front surface structure, wherein
the applying the protective film to the front surface of the semiconductor wafer includes applying the protective film above the passivation film, and
the protective film is thinner than the passivation film.

8. The fabrication method of the semiconductor device according to claim 4, the fabrication method further comprising:
forming a front surface structure in the front surface of the semiconductor wafer; and
forming a passivation film above the front surface structure, wherein
the applying the protective film to the front surface of the semiconductor wafer includes applying the protective film above the passivation film, and
the protective film is thinner than the passivation film.

9. The fabrication method of the semiconductor device according to claim 5, wherein
a thickness of the protective film is greater than or equal to 2 μm and less than or equal to 5 μm.

10. The fabrication method of the semiconductor device according to claim 1, wherein
a glass transition temperature of the protective film is greater than or equal to 200 degrees.

11. The fabrication method of the semiconductor device according to claim 1, wherein
a thermal decomposition temperature of the protective film is greater than or equal to 300 degrees and less than or equal to 600 degrees.

12. The fabrication method of the semiconductor device according to claim 1, wherein
the patterning the protective film includes
forming a mask with a predetermined shape in the protective film, and
etching the protective film using the mask.

13. The fabrication method of the semiconductor device according to claim 12, wherein
the mask is a photoresist.

14. The fabrication method of the semiconductor device according to claim 12, the fabrication method further comprising:
heating the protective film after the protective film is patterned.

15. The fabrication method of the semiconductor device according to claim 1, wherein
the patterning the protective film includes leaving the protective film at a pitch that is greater than or equal to 20 μm and less than or equal to 0.3 mm.

16. The fabrication method of the semiconductor device according to claim 1, wherein
the patterning the protective film includes leaving the protective film in a manner that a longest length of a shape becomes greater than or equal to 3 μm and less than or equal to 0.2 mm.

17. The fabrication method of the semiconductor device according to claim 1, wherein
the patterning the protective film includes leaving the protective film in a manner that a protection rate of the front surface by the protective film becomes greater than or equal to 3% and less than or equal to 30%.

18. The fabrication method of the semiconductor device according to claim 1, wherein
the support stand has a plurality of protruding portions in a surface where the protective film that is patterned of the front surface is held, and
the performing the backside processing includes performing backside processing of the semiconductor wafer in a state in which the protective film that is patterned is supported by the plurality of protruding portions.

19. The fabrication method of the semiconductor device according to claim 18, wherein
a pitch of the protective film that is patterned is less than a longest length of the protruding portions.

20. The fabrication method of the semiconductor device according to claim 18, wherein
the support stand has an annular protruding portion on an outer edge side of the surface where the protective film that is patterned of the front surface is held, and
the patterning the protective film includes forming an annular pattern corresponding to the annular protruding portion in the front surface.
